(19) United States
(12) Patent Application Publication
(10) Pub. No.: US 2010/0314755 A1
(43) Pub. Date: Dec. 16, 2010

(54) PRINTED CIRCUIT BOARD, SEMICONDUCTOR DEVICE COMPRISING THE SAME, AND METHOD OF MANUFACTURING THE SAME

(76) Inventors: Myung Sam KANG, Gyunggi-do (KR); Mi Sun Hwang, Gyunggi-do (KR); Ok Tae Kim, Gyunggi-do (KR); Seon Ha Kang, Gyunggi-do (KR); Gil Yong Shin, Jeollabuk-do (KR); Kil Yong Yun, Gyunggi-do (KR); Min Jung Cho, Gyunggi-do (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/511,723

(22) Filed: Jul. 29, 2009

(30) Foreign Application Priority Data
Jun. 12, 2009 (KR) 10-2009-0052471

(51) Int. Cl. H01L 23/498; H05K 1/11; B05D 5/12; B32B 38/00

(52) U.S. Cl. 257/737; 174/266; 427/96.9; 156/278; 156/230; 257/E23.06

(57) ABSTRACT

Disclosed is a printed circuit board, which includes a first circuit layer embedded in one surface an insulating layer and including a bump pad and a wire bonding pad, thus realizing a high-density wire bonding pad. A semiconductor device including the printed circuit board and a method of manufacturing the printed circuit board are also provided.

### CROSS REFERENCE TO RELATED APPLICATION

This application claims the benefit of Korean Patent Application No. 10-2009-0052471, filed Jun. 12, 2009, entitled “A printed circuit board and a device comprising the same, and method of manufacturing the same”, which is hereby incorporated by reference in its entirety into this application.

### BACKGROUND OF THE INVENTION

1. Field of the Invention

The present invention relates to a printed circuit board (PCB), a semiconductor device including the same, and a method of manufacturing the same.

2. Description of the Related Art

With the advancement of the electronics industry, the application of a package including a memory chip to many electronic devices is increasing, and manufacturers which manufacture and supply such a package are also increasing. Such market circumferences raise the price competitiveness of the package including the memory chip, and thus the manufacturing cost of the package is gradually going down, and also, various methods of reducing the manufacturing cost are being devised.

Most of the memory packages are manufactured in a manner such that the memory chip is connected to the substrate using wire bonding to thus form a package, and the resultant substrate is referred to as a BOC (Board-on-Chip).

FIG. 1 is a cross-sectional view showing a conventional BOC. As shown in FIG. 1, the BOC is a substrate which is specially developed so as to be adapted to suit the properties of a memory chip 50. The BOC is configured such that a terminal of the memory chip 50 is located at the center thereof and is directly connected to a substrate 10 to increase a signal processing speed, and solder balls 70 are mounted on a surface of the substrate on which wire bonding pads 15 are formed. Specifically, the chip 50 is attached to the lower surface of the substrate 10 using an adhesive 30, and a slot is formed at a portion of the substrate where the terminal is located in order to directly connect the terminal of the chip to the bonding pads 15 of the substrate 10, thus achieving bonding of a wire 60 through the slot. Hence, conventionally, the metal layer 13 of the BOC is simply provided in the form of a single layer, and the manufacturing cost thereof is low, so that the BOC gains the upper hand in terms of price competiveness of memory package.

However, alongside the rapid development of techniques for manufacturing the semiconductor, the increasing capacity of the memory package is also taking place.

Because of the development of such techniques, in the case of the substrate for a BOC, in order to correspond to an increase in the number of IO counts of an IC, the wire bonding pad pitch is required to be further fined. Conventionally, a copper etching process is utilized for the fabrication of the circuit of the BOC. In this case, when the wire bonding pad pitch is required to be 80 μm or less, it is impossible to ensure a top width of the pad which is required for wire bonding.

FIG. 2 is an enlarged cross-sectional view schematically showing the wire bonding pads formed on the insulating layer. As shown in FIG. 2, because the distance D between the neighboring pads must be 20 μm or more, the bottom width W1 of the circuit is set to 60 μm to form the pitch W1+D of 80 μm. As such, when the bottom width W1 of the circuit is 60 μm, the top width W2 of the circuit is reduced to about 35 μm. However, in the case where the top width W2 of the circuit is 35 μm, wire bonding is impossible, and thus the pitch W1+D of 80 μm cannot be manufactured.

### SUMMARY OF THE INVENTION

Accordingly, the present invention has been made keeping in mind the problems encountered in the related art and the present invention intends to provide a PCB which is capable of forming high-density wire bonding pads, a semiconductor device including the PCB, and a method of manufacturing the PCB.

An aspect of the present invention provides a PCB, including an insulating layer made of an electrical insulating material, a first circuit layer embedded in one surface of the insulating layer and including a bump pad and a wire bonding pad, a second circuit layer formed in the other surface of the insulating layer, and a slot formed to pass through the insulating layer so as to achieve wire bonding.

The PCB may further include an assistant substrate which has an extension of the slot at a position corresponding to the slot formed in the insulating layer and which is attached to the surface of the insulating layer in which the second circuit layer is formed.

The PCB may further include a solder resist layer formed on the surface of the insulating layer in which the first circuit layer is embedded.

The PCB may further include an adhesive layer formed between the insulating layer and the assistant substrate.

The solder resist layer may have an opening for exposing the slot, the bump pad and the wire bonding pad.

Another aspect of the present invention provides a semiconductor device, including a PCB which includes an insulating layer made of an electrical insulating material, a first circuit layer embedded in one surface of the insulating layer and including a bump pad and a wire bonding pad, a second circuit layer embedded in the other surface of the insulating layer and a slot formed to pass through the insulating layer so as to achieve wire bonding; and a semiconductor chip attached to one surface of an assistant substrate of the PCB.

The semiconductor device may further include an adhesive layer formed between the insulating layer and the assistant substrate.

A further aspect of the present invention provides a semiconductor device, including a PCB which includes an insulating layer made of an electrical insulating material, a first circuit layer embedded in one surface of the insulating layer and including a bump pad and a wire bonding pad, a second circuit layer embedded in the other surface of the insulating layer, a slot formed to pass through the insulating layer so as to achieve wire bonding and an assistant substrate having an extension of the slot at a position corresponding to the slot formed in the insulating layer and attached to the surface of the insulating layer in which the second circuit layer is formed; and a semiconductor chip attached to the assistant substrate.

The semiconductor device may further include an adhesive layer formed between the insulating layer and the assistant substrate.

The semiconductor chip may be disposed such that an external connection terminal of the semiconductor chip is exposed through the slot.

Still another aspect of the present invention provides a method of manufacturing the PCB, including (A) providing an insulating layer, and forming a first circuit layer embedded in one surface of the insulating layer and including a bump pad and a wire bonding pad, and a second circuit layer embedded in the other surface of the insulating layer, and (B) forming a slot to pass through the insulating layer so as to achieve wire bonding.

Attaching an assistant substrate to the surface of the insulating layer in which the second circuit layer is formed may be further performed after (A), and (B) may be performed by forming the slot to pass through the insulating layer and the assistant substrate so as to achieve wire bonding.

Yet another aspect of the present invention provides a method of manufacturing the PCB, including (A) providing an assistant substrate attached to a carrier, (B) attaching a circuit substrate including an insulating layer and circuit layers embedded in both surfaces of the insulating layer onto the assistant substrate, (C) forming a solder resist layer on one surface of the circuit substrate, (D) separating the assistant substrate from the carrier, and (E) forming a slot to pass through the circuit substrate and the assistant substrate.

The method may further include forming a via for electrically connecting the circuit layers embedded in both surfaces of the insulating layer, after (B).

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing a conventional BOC;

FIG. 2 is an enlarged cross-sectional view schematically showing wire bonding pads formed on an insulating layer of the BOC of FIG. 1;

FIG. 3 is a top plan view showing a PCB according to an embodiment of the present invention;

FIG. 4 is a transverse cross-sectional view showing the PCB of FIG. 3;

FIG. 5 is a cross-sectional view showing a semiconductor device according to another embodiment of the present invention;

FIG. 6 is an enlarged cross-sectional view schematically showing wire bonding pads formed in an insulating layer of the PCB of FIG. 4; and

FIGS. 7 to 18 are cross-sectional views sequentially showing a process of manufacturing the PCB according to a further embodiment of the present invention.

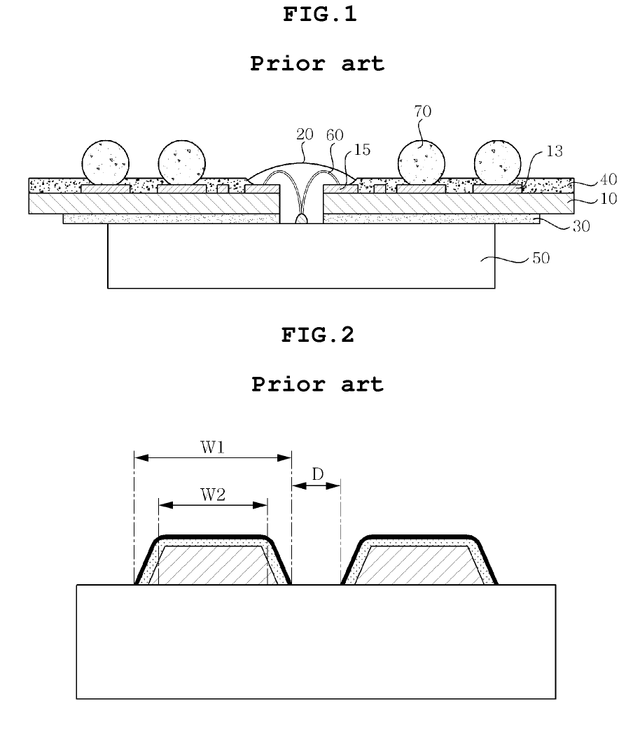

### DESCRIPTION OF SPECIFIC EMBODIMENTS

Hereinafter, a detailed description will be given of a PCB, a semiconductor device including the PCB and a method of manufacturing the PCB according to embodiments of the present invention with reference to the accompanying drawings. Throughout the drawings, the same reference numerals refer to the same or similar elements, and redundant descriptions are omitted. In the description, the terms “upper”, “lower” and so on are used only to distinguish one element from another element, and the elements are not defined by the above terms.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

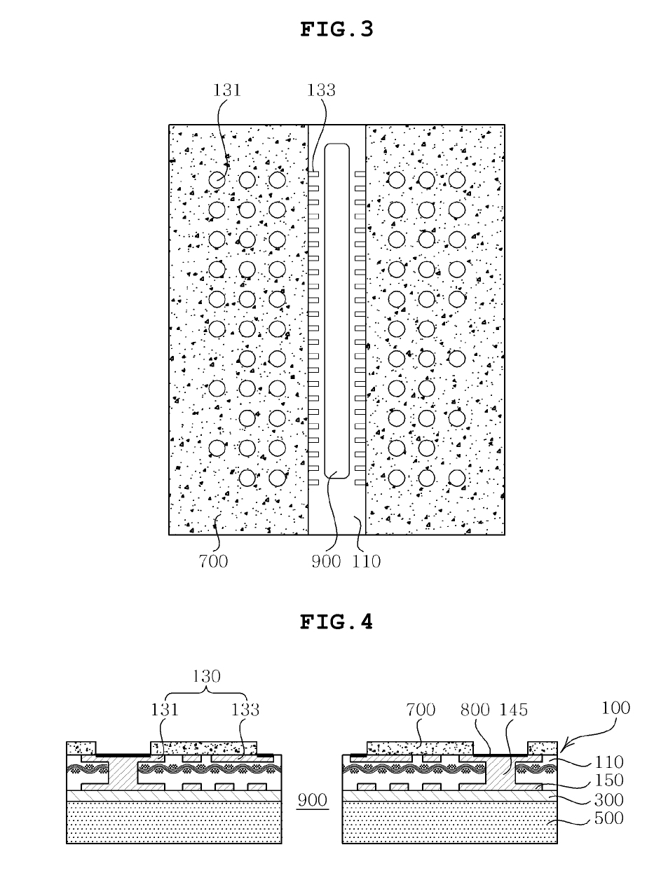

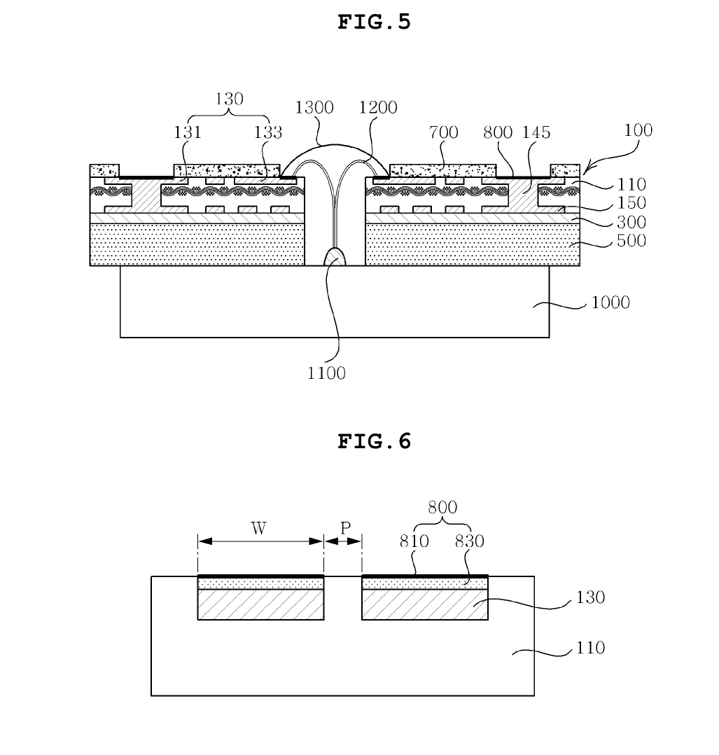

FIG. 3 is a top plan view showing a PCB according to an embodiment of the present invention, FIG. 4 is a transverse cross-sectional view showing the PCB of FIG. 3, and FIG. 5 is a cross-sectional view showing a semiconductor device according to another embodiment of the present invention.

As shown in FIGS. 3 and 4, the PCB according to the present embodiment includes an insulating layer 110 made of an electrical insulating material, a first circuit layer 130 and a second circuit layer 150 embedded in both surfaces of the insulating layer 110, and a slot 900 formed to pass through the insulating layer for purposes of wire bonding.

The insulating layer 110 is made of an electrical insulating material which is typically used in the fabrication of PCBs, and includes, for example, an epoxy-based thermosetting resin, a photocurable resin, or a prepreg.

The circuit layers 130, 150 form a metal pattern for transferring an electrical signal and are formed of a metal having high electrical conductivity, such as gold, silver, copper, or nickel. In the present embodiment, the circuit layers 130, 150 are embedded in both surfaces of the insulating layer 110. In the present embodiment, the circuit layers 130, 150 are embedded, which means that a circuit layer is embedded in the insulating layer 110 so as to expose only one surface of the circuit layer. Also, an embodiment in which the second circuit layer 150 is not embedded in the insulating layer is possible.

The circuit layers 130, 150 according to the present embodiment may be divided into the first circuit layer 130 embedded in one surface of the insulating layer 110 and including bump pads 131 and wire bonding pads 133, and into the second circuit layer 150 embedded in the other surface of the insulating layer 110. Specifically, formed in the first circuit layer 130 are the bump pads 131 on which bumps (solder balls) for electrical connection to an external substrate are formed, and the wire bonding pads 133 for wire bonding with the semiconductor chip 1000 mounted on the PCB. As shown in FIG. 3, when the wire bonding pads 133 are formed around the slot 900, the length of the wire may be reduced. Also, because the second circuit layer 150 is formed in a direction in which the semiconductor chip 1000 is mounted, it typically does not include the bump pads 131 or the wire bonding pads 133.

The slot 900 is a through hole for wire bonding formed to pass through the insulating layer 110 in order to electrically connect the semiconductor chip 1000 mounted on the PCB and the PCB to each other. The slot 900 may be located at the center of the PCB, and may be typically provided in the form of a bar shape having a long length relative to a width.

Also, the PCB according to the present embodiment may further include an assistant substrate 500 attached to one surface of the insulating layer 110. The assistant substrate 500 is an assistant member attached to impart rigidness to the PCB. Thus, in the case where the PCB itself has sufficient rigidness, there is no need for an assistant substrate 500. The material for the assistant substrate 500 is not particularly limited, and any material may be used as long as it imparts rigidness to the PCB. The assistant substrate 500 may be made of a polymer resin similar to that of the insulating layer 110 as described above. Alternatively, glass or plastic may be used. The assistant substrate 500 is particularly exemplified by an epoxy prepreg containing a reinforcing material such as glass fiber.

The assistant substrate 500 has an extension of the slot 900 at a position corresponding to the slot 900 formed in the insulating layer 110, and is attached to the surface of the insulating layer 110 in which the second circuit layer 150 is formed. Also, an additional adhesive layer 300 may be interposed between the insulating layer 110 and the assistant substrate 500 in order to attach the assistant substrate 500 to the PCB. The extension of the slot 900 provides the bonding pathway of the wire 1200 for connecting the semiconductor chip 1000 and the PCB, like the slot 900.

Also, the PCB according to the present embodiment may further include a solder resist layer 700 formed on the surface of the insulating layer 110 in which the first circuit layer 130 is embedded. The solder resist layer 700 enables the circuit layer which is exposed to the outside to be protected from corrosion or contamination. The solder resist layer 700 has openings for exposing the slot 900, the bump pads 131, and the wire bonding pads 133. A surface protective layer 800 made of nickel 830/gold 810 may be formed on the bump pads 131 or the wire bonding pads 133 exposed from the solder resist layer 700.

As mentioned above, the PCB is advantageous because the circuit layers are embedded in the insulating layer 110, and thus a high-density circuit pattern can be accomplished. Specifically, as shown in FIG. 6, because the circuit layers 130, 150 according to the present embodiment have the same top and bottom widths, even when the wire bonding pads 133 are required to have a predetermined width W or more, the circuit pattern can be designed without a need to consider a decrement in the top width. Thus, the pitch W+P between the neighboring circuits can be virtually reduced, thereby enabling the formation of the high-density circuit pattern.

Also, because the PCB according to the present embodiment includes at least two circuit layers including the first circuit layer 130 and the second circuit layer 150, a higher-density circuit pattern can be formed, compared to a PCB having a single circuit layer.

Also, because the PCB further includes the assistant substrate 500 for imparting rigidness thereto, rigidness can be assured even in the case where the circuit layers are formed in the thin insulating layer 110 enabling the formation of the high-density circuit pattern.

FIG. 5 is a cross-sectional view showing a semiconductor device including the PCB of FIG. 4 and the semiconductor chip 1000 mounted on the PCB.

The semiconductor chip 1000 includes a chip body made of silicon material and including an IC (not shown) and an external connection terminal 1100 formed on one surface of the chip body and electrically connected with the IC. The semiconductor chip 1000 may be a memory chip or a logic chip including an electronic circuit or logic circuit. As shown in FIG. 5, the semiconductor chip 1000 is attached to one surface of the assistant substrate 500 of the PCB.

The semiconductor chip 1000 is disposed such that the external connection terminal 1100 of the semiconductor chip 1000 is exposed through the slot 900. The external connection terminal 1100 of the semiconductor chip 1000 is connected to the wire bonding pads 133 of the first circuit layer 130 by the wire 1200. Specifically, the wire 1200 is disposed to pass through the slot 900 formed in the insulating layer 110 and the extension of the slot 900 formed in the assistant substrate 500, so that the external connection terminal 1100 of the semiconductor chip 1000 is electrically connected to the wire bonding pads 133. The wire 1200 is protected by an encapsulation layer 1300.

Although not shown, in the case where the assistant substrate 500 is not provided, the semiconductor chip 1000 may be directly attached to the surface of the PCB in which the second circuit layer 150 is formed.

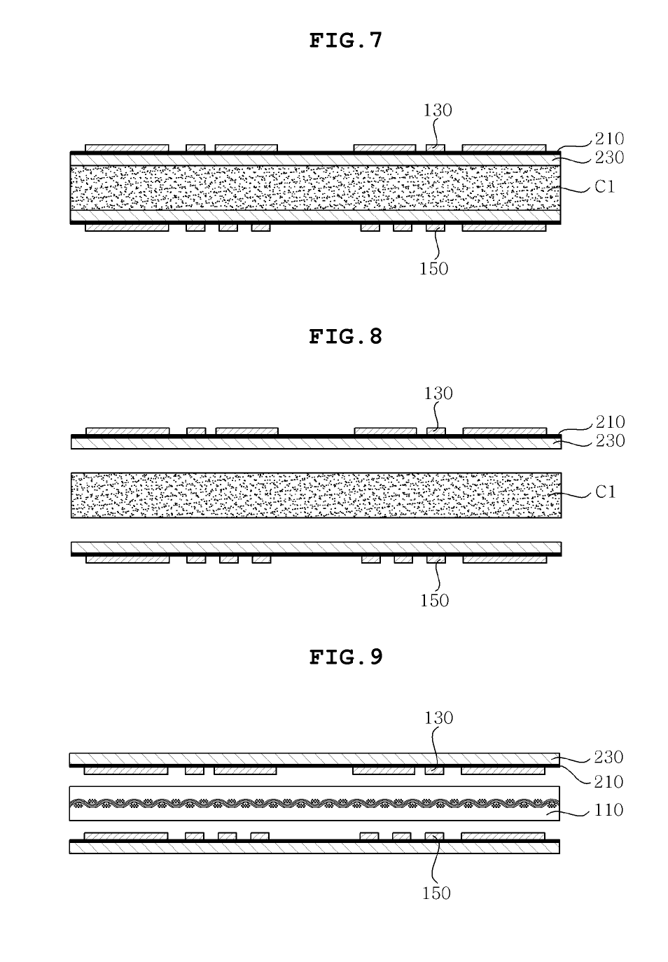

FIGS. 7 to 18 sequentially show a process of manufacturing the PCB according to a further embodiment of the present invention. Below, the method of manufacturing the PCB according to the present embodiment is specified with reference to the above drawings.

The insulating layer 110 is provided, after which the first circuit layer 130 including the bump pads 131 and the wire bonding pads 133 is formed in one surface of the insulating layer 110, and the second circuit layer 150 is formed in the other surface of the insulating layer 110.

As shown in FIG. 7, the first circuit layer 130 and the second circuit layer 150 are respectively formed on metal carriers 230 having a low coefficient of thermal expansion on both surfaces of a first carrier. A metal layer 210 is interposed between the metal carriers 230 and the circuit layers 130, 150, and the first circuit layer 130 and the second circuit layer 150 may be respectively formed on the metal carriers 230 attached to both surfaces of the first carrier. The metal carriers 230 are made of a metal having a low coefficient of thermal expansion, such as SUS304, Inver or Kover, in order to prevent deformation of the substrate such as expansion or warping depending on changes in atmospheric temperature or process temperature.

The metal layer 210 may be removed through flash etching in a subsequent process, like an electroless copper plating layer formed through electroless plating, and may be formed by disposing a conductive foil on the metal carriers 230, like a copper foil. The first circuit layer 130 and the second circuit layer 150 may be formed through electroplating using a plating resist.

Next, as shown in FIG. 8, after the formation of the first circuit layer 130 and the second circuit layer 150, the metal carriers 230 are separated from the first carrier.

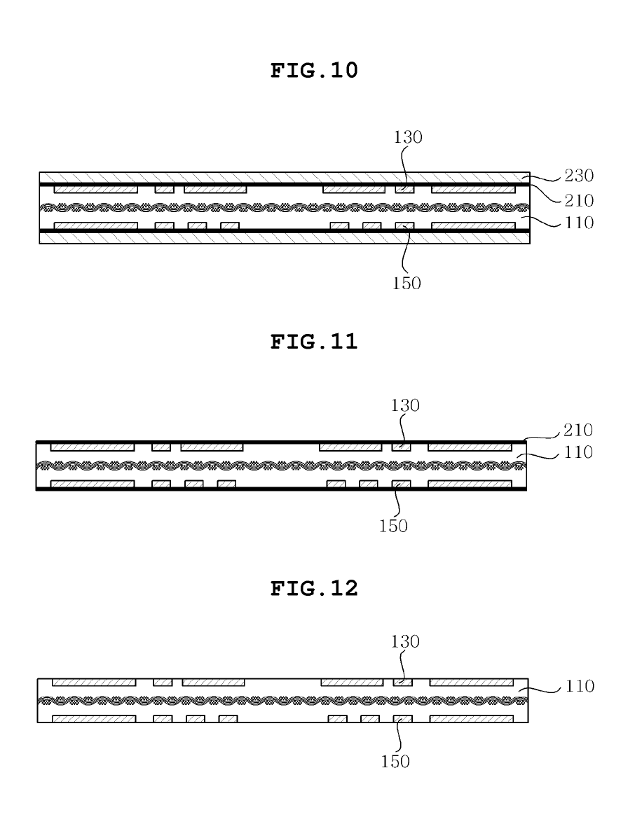

Next, as shown in FIG. 9, the insulating layer 110 is provided, after which the first circuit layer 130 and the second circuit layer 150 are disposed to face the insulating layer 110, and then heat compressed using a press, so that the first circuit layer 130 and the second circuit layer 150 are inserted into the insulating layer 110, as shown in FIG. 10.

Next, as shown in FIG. 11, the metal carriers 230 are removed. The metal layer 210 and the metal carriers 230 may be formed using selectively etchable heterogeneous metals, and thus the metal carriers 230 may be removed through etching.

Next, as shown in FIG. 12, the metal layer 210 is removed through flash etching, thereby obtaining a circuit substrate including the insulating layer 110 and the circuit layers embedded in both surfaces of the insulating layer 110. Thereafter, vias 145 for electrically connecting the first circuit layer 130 and the second circuit layer 150 are formed, and the slot 900 is formed in the insulating layer 110, thus consequently manufacturing the PCB according to the embodiment of the present invention. Below, the embodiment in which the assistant substrate 500 is used is described.

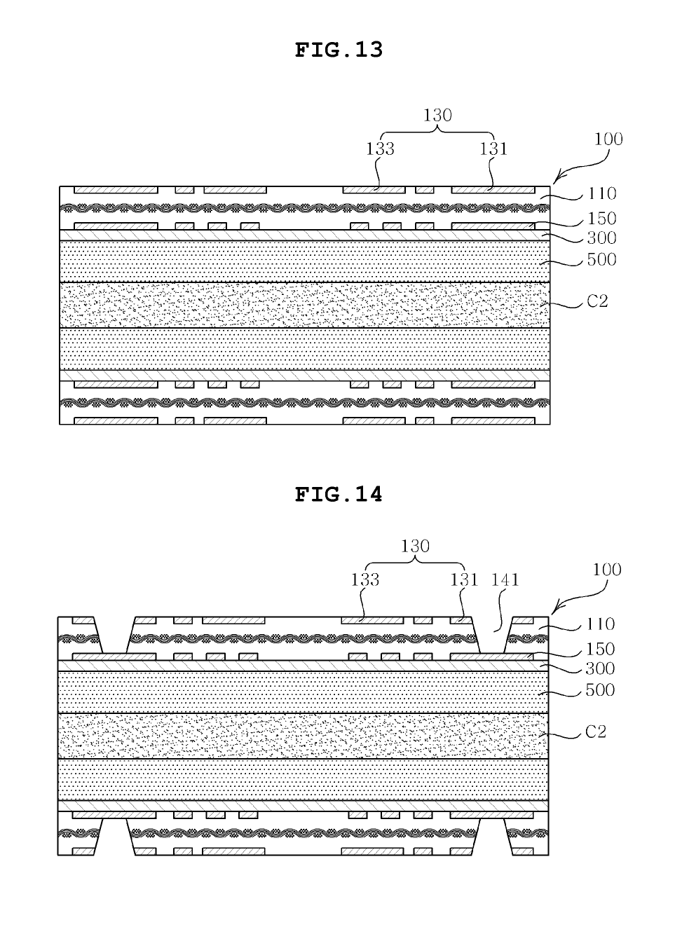

As shown in FIG. 13, the assistant substrate 500 is attached to the surface of the insulating layer 110 in which the second circuit layer 150 is formed. The assistant substrate 500 may be provided in a form of being attached to a second carrier, as seen in the drawing. Herein, simultaneous manufacture of two PCBs using the second carrier is illustrated. An adhesive layer 300 is interposed between the assistant substrate 500 and the insulating layer 110, and the circuit substrate including the insulating layer 110 and the circuit layers embedded in both surfaces of the insulating layer 110 is attached onto the assistant substrate 500.

Next, as shown in FIG. 14, via holes 141 for electrically connecting the first circuit layer 130 and the second circuit layer 150 are formed. For example, the via holes 141 may be formed using a CO₂ laser drill.

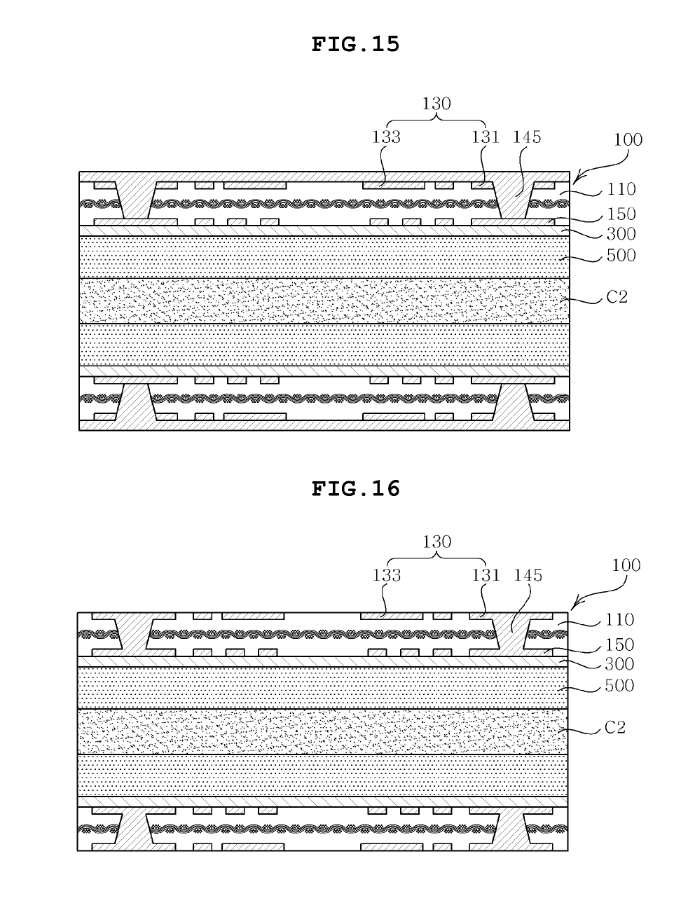

Next, as shown in FIG. 15, the vias 145 resulting from filling the via holes 141 through a plating process are formed. As such, the plating layer may be formed not only in the via holes 141 but also on the first circuit layer 130.

Next, as shown in FIG. 16, etching is performed until the first circuit layer 130 is exposed, thus removing the plating layer formed on the insulating layer 110, thereby completing the vias 145 for electrically connecting the circuit layers embedded in both surfaces of the insulating layer 110.

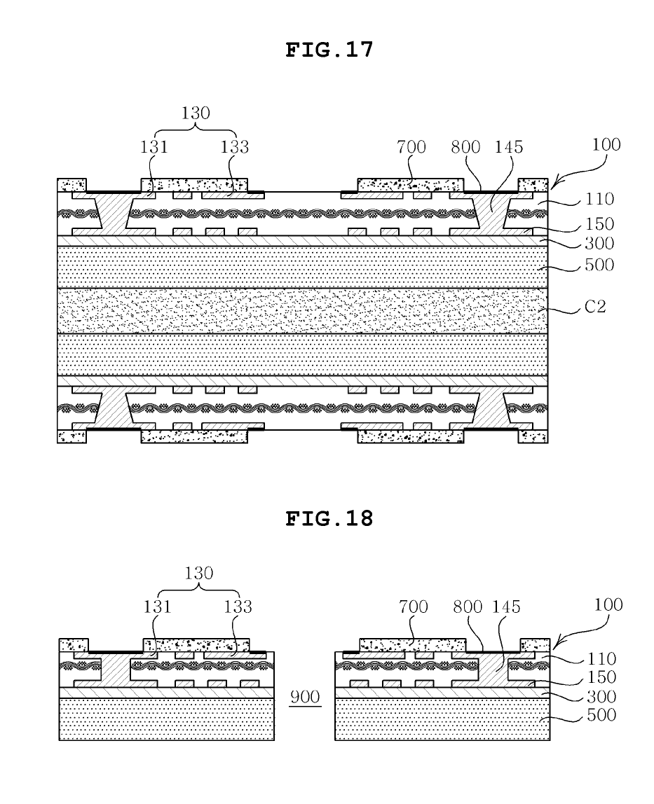

Next, as shown in FIG. 17, the solder resist layer 700 is formed on one surface of the circuit substrate. After the formation of the solder resist layer 700, the surface protective layer 800 made of nickel 830 and gold 810 may be further formed on the surfaces of the bump pads 131 and the wire bonding pads 133 exposed from the solder resist layer 700.

Next, as shown in FIG. 18, the assistant substrate 500 is separated from the second carrier, and the slot 900 for wire bonding is formed to pass through the circuit substrate and the assistant substrate 500. The slot 900 may be formed using a CNC drill, a laser drill or a punch.

As described hereinbefore, the present invention provides a PCB, a semiconductor device including the same, and a method of manufacturing the same. According to the present invention, the PCB is advantageous because circuit layers are embedded in an insulating layer, and thus high-density wire bonding pads can be realized.

Also, according to an embodiment of the present invention, the PCB includes at least two circuit layers including first and second circuit layers, thus enabling the formation of a higher-density circuit pattern, compared to a PCB including a single circuit layer.

Also, an assistant substrate for imparting rigidness to the PCB is further included, and thus rigidness can be assured even in the case where the circuit layers are formed in a thin insulating layer enabling the formation of a high-density circuit pattern.

Although the embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

1. A printed circuit board, comprising:
an insulating layer made of an electrical insulating material;
a first circuit layer embedded in one surface of the insulating layer and including a bump pad and a wire bonding pad;
a second circuit layer formed in the other surface of the insulating layer; and
a slot formed to pass through the insulating layer so as to achieve wire bonding.

2. The printed circuit board as set forth in claim 1, further comprising an assistant substrate which has an extension of the slot at a position corresponding to the slot formed in the insulating layer and which is attached to the surface of the insulating layer in which the second circuit layer is formed.

3. The printed circuit board as set forth in claim 1, further comprising a solder resist layer formed on the surface of the insulating layer in which the first circuit layer is embedded.

4. The printed circuit board as set forth in claim 2, further comprising an adhesive layer formed between the insulating layer and the assistant substrate.

5. The printed circuit board as set forth in claim 3, wherein the solder resist layer has an opening for exposing the slot, the bump pad and the wire bonding pad.

6. A semiconductor device, comprising:
a printed circuit board, comprising:
an insulating layer made of an electrical insulating material,
a first circuit layer embedded in one surface of the insulating layer and including a bump pad and a wire bonding pad,
a second circuit layer embedded in the other surface of the insulating layer, and
a slot formed to pass through the insulating layer so as to achieve wire bonding; and
a semiconductor chip attached to one surface of an assistant substrate of the printed circuit board.

7. The semiconductor device as set forth in claim 6, further comprising an adhesive layer formed between the insulating layer and the assistant substrate.

8. A semiconductor device, comprising:
a printed circuit board, comprising:
an insulating layer made of an electrical insulating material,
a first circuit layer embedded in one surface of the insulating layer and including a bump pad and a wire bonding pad,
a second circuit layer embedded in the other surface of the insulating layer,
a slot formed to pass through the insulating layer so as to achieve wire bonding, and
an assistant substrate having an extension of the slot at a position corresponding to the slot formed in the insulating layer and attached to the surface of the insulating layer in which the second circuit layer is formed; and
a semiconductor chip attached to the assistant substrate.

9. The semiconductor device as set forth in claim 8, further comprising an adhesive layer formed between the insulating layer and the assistant substrate.

10. The semiconductor device as set forth in claim 8, wherein the semiconductor chip is disposed such that an external connection terminal of the semiconductor chip is exposed through the slot.

11. The semiconductor device as set forth in claim 10, further comprising a wire disposed to pass through the slot and the extension of the slot so as to electrically connect the external connection terminal of the semiconductor chip and the wire bonding pad to each other.

12. (canceled)

13. (canceled)

14. (canceled)

15. (canceled)
